(19) United States
(12) Patent Application Publication
(10) Pub. No.: US 2024/0187033 A1
(43) Pub. Date: Jun. 6, 2024

(54) RADIO FREQUENCY MODULE AND COMMUNICATION DEVICE

(71) Applicant: Murata Manufacturing Co., Ltd., Nagaokakyo-shi (JP)

(72) Inventors: Hiroki SHOUNAI, Nagaokakyo-shi (JP); Yukiya YAMAGUCHI, Nagaokakyo-shi (JP); Atsushi HORITA, Nagaokakyo-shi (JP); Hiroyuki YAMAMOTO, Nagaokakyo-shi (JP); Yukiko MATSUDA, Nagaokakyo-shi (JP)

(73) Assignee: Murata Manufacturing Co., Ltd., Nagaokakyo-shi (JP)

(21) Appl. No.: 18/442,125

(22) Filed: Feb. 15, 2024

Related U.S. Application Data
(63) Continuation of application No. PCT/JP2022/030450, filed on Aug. 9, 2022.

(30) Foreign Application Priority Data
Aug. 20, 2021 (JP) 2021-134694

(51) Int. Cl. H04B 1/40

(52) U.S. Cl. CPC H04B 1/40

(57) ABSTRACT

A radio frequency module includes a module substrate including a first main surface facing a second main surface, and a power amplifier including first and second power amplification devices and an output transformer, which includes a primary coil and a secondary coil, and a capacitor connected to the output transformer. One end of the primary coil is connected to the first amplification device. Another end of the primary coil is connected to the second amplification device. One end of the secondary coil is connected to an output terminal. The output transformer is disposed in or on the module substrate and is disposed closer to one of the first and second main surfaces than the other. The capacitor is disposed in or on the other of the first and second main surfaces and is disposed to overlap the output transformer when the module substrate is viewed in a plan view.

### CROSS-REFERENCE TO RELATED APPLICATIONS

This application is a continuation of international application no. PCT/JP2022/030450, filed Aug. 9, 2022, which claims priority to Japanese application no. JP 2021-134694, filed Aug. 20, 2021. The entire contents of both prior applications are hereby incorporated by reference.

### TECHNICAL FIELD

The present disclosure relates to a radio frequency module and a communication device.

### BACKGROUND ART

Mobile communication devices such as cellular phones are equipped with power amplifiers that amplify radio frequency transmission signals.

A radio frequency module may include a differential amplification type amplifier. The output terminals of two amplification devices constituting the differential amplification type amplifier are connected to a primary coil of an output transformer. The differential amplification type amplifier further includes a capacitor connected between a middle point of the primary coil and ground and a capacitor that connects the output terminals of the amplification devices. In a case where these components are disposed in or on a module substrate, for example, the output transformer is disposed inside the module substrate, and the capacitors are disposed so as not to overlap the output transformer in a plan view such that the transmission loss of signals is not increased by disturbing the magnetic field generated by the output transformer.

### CITATION LIST

### Patent Document

Patent Document 1: Japanese Unexamined Patent Application Publication No. 2021-61577

### SUMMARY

### Technical Problem

However, in a case where the module substrate is viewed in a plan view in the differential amplification type amplifier, the output transformer and the capacitors are disposed at different positions, thereby increasing the size of the radio frequency module.

The present disclosure has been made to solve the above-described problem, and exemplary aspects of the present disclosure provide a compact radio frequency module and a compact communication device.

### Solution to Problem

In order to achieve the above-described object, a radio frequency module according to an exemplary embodiment of the present disclosure includes a module substrate including a first main surface that faces a second main surface, and a power amplifier that amplifies a transmission signal. The power amplifier includes a first amplification device and a second amplification device, an output transformer including a first coil and a second coil, and a capacitor connected to the output transformer. One end of the first coil is connected to an output terminal of the first amplification device, another end of the first coil is connected to an output terminal of the second amplification device, and one end of the second coil is connected to an output terminal of the power amplifier. The output transformer is disposed in or on the module substrate and is disposed closer to one of the first main surface and the second main surface than to an other of the first main surface and the second main surface. The capacitor is disposed in or on the other one of the first main surface and the second main surface, and is disposed to overlap the output transformer in a case where the module substrate is viewed in a plan view.

### Advantageous Effects

According to the present disclosure, it becomes possible to provide a compact radio frequency module and a compact communication device.

### BRIEF DESCRIPTION OF DRAWINGS

FIG. 1 is a circuit configuration diagram of a radio frequency module and a communication device according to an exemplary embodiment.

FIG. 2 is a circuit configuration diagram of a power amplifier, which is of a differential amplification type, according to the exemplary embodiment.

FIG. 3A includes plan views of a radio frequency module according to an example.

FIG. 3B is a cross-sectional view of a radio frequency module according to the example.

FIG. 4A is a cross-sectional view of a radio frequency module according to a first modification.

FIG. 4B is a cross-sectional view of a radio frequency module according to a second modification.

FIG. 4C is a cross-sectional view of a radio frequency module according to a third modification.

FIG. 5 is a circuit configuration diagram of a Doherty power amplifier according to a fourth modification.

FIG. 6A includes plan views of a radio frequency module according to the fourth modification.

FIG. 6B is a cross-sectional view of the radio frequency module according to the fourth modification.

### DETAILED DESCRIPTION

In the following, exemplary embodiments of the present disclosure will be described in detail. Note that the exemplary embodiments described below are intended to represent both comprehensive and specific examples. Numerical values, shapes, materials, constituent elements, arrangement and connection forms of the constituent elements, and so forth described in the following exemplary embodiments are examples and are not intended to limit the present disclosure. Among the constituent elements in the following examples and modifications, the constituent elements that are not described in the independent claims are described as optional constituent elements. The sizes or size ratios of the constituent elements illustrated in the drawings are not necessarily exact. In each drawing, substantially identical configurations are denoted by the same signs, and redundant description may be omitted or simplified.

In addition, in the following, terms indicating relationships between elements, such as parallel and perpendicular, terms indicating element shapes, such as rectangular, and numerical ranges do not express strict meanings only, but are also meant to include substantially equivalent ranges, such as ranges with differences of about a few percent.

In the following diagrams, the x-axis and the y-axis are axes orthogonal to each other on a plane parallel to a main surface of a module substrate. Specifically, in a case where the module substrate is rectangular in a plan view, the x-axis is parallel to a first side of the module substrate, and the y-axis is parallel to a second side of the module substrate orthogonal to the first side. Moreover, the z-axis is an axis perpendicular to the main surface of the module substrate, and its positive direction indicates the upward direction and its negative direction indicates the downward direction.

In circuit configurations of the present disclosure, “connected” includes not only cases where direct connection is established by a connection terminal, a wiring conductor, or a connection terminal and a wiring conductor but also cases where electrical connection is established using other circuit elements. “Connected between A and B” refers to being disposed between A and B and connected to both A and B, and includes cases of being directly connected to a path connecting A and B and also cases of being connected in parallel (shunt-connected) between the path and ground.

In the arrangement of components of the present disclosure, “a module substrate is viewed in a plan view” refers to viewing an object from the positive side of the z-axis in an orthographic projection onto the xy-plane. “A is disposed between B and C” means that at least one of line segments connecting any point within B and any point within C passes through A. “The distance between A and B in a case where the module substrate is viewed in a plan view” refers to the length of a line segment connecting a representative point within the region of A and a representative point within the region of B in the orthographic projection onto the xy-plane. In this case, as the representative points, the center points of these regions or the points closest to the counterpart regions can be used; however, the representative points are not limited to these points. In addition, terms indicating relationships between elements, such as “parallel” and “perpendicular”, terms indicating element shapes, such as “rectangular”, and numerical ranges do not express strict meanings only, but are also meant to include substantially equivalent ranges, such as ranges with errors of about a few percent.

In the arrangement of components of the present disclosure, “a component is disposed in or on a substrate” includes cases where the component is disposed on a main surface of the substrate and cases where the component is disposed inside the substrate. “A component is disposed on a main surface of a substrate” includes cases where the component is disposed so as to be in contact with the main surface of the substrate and also cases where the component is disposed above the main surface without being in contact with the main surface (for example, cases where the component is stacked on another component that is disposed so as to be in contact with the main surface). Moreover, “a component is disposed on a main surface of a substrate” may include cases where the component is disposed in a recess formed in the main surface. “A component is disposed inside a substrate” includes cases where the component is encapsulated in the module substrate and also includes cases where the entirety of the component is disposed between the main surfaces of the substrate but part of the component is not covered by the substrate and cases where only part of the component is disposed inside the substrate.

Moreover, in the present disclosure, “electronic components” refers to components including active elements, passive elements, or active and passive elements. That is, electronic components include active components including transistors, diodes, or the like, and passive components including inductors, transformers, capacitors, resistors, or the like but do not include electromechanical components including terminals, connectors, wiring lines, or the like.

In the following, “signal paths” refers to wiring lines through which signals propagate, electrodes directly connected to the wiring lines, and transmission lines constituted by terminals and so forth directly connected to the wiring lines or the electrodes. “Transmission paths” refers to wiring lines through which radio frequency transmission signals propagate, electrodes directly connected to the wiring lines, and transmission lines constituted by terminals and so forth directly connected to the wiring lines or the electrodes. “Reception paths” refers to wiring lines through which radio frequency reception signals propagate, electrodes directly connected to the wiring lines, and transmission lines constituted by terminals and so forth directly connected to the wiring lines or the electrodes. “Transmission-reception paths” refers to wiring lines through which radio frequency transmission signals and radio frequency reception signals propagate, electrodes directly connected to the wiring lines, and transmission lines constituted by terminals and so forth directly connected to the wiring lines or the electrodes.

### Embodiments

### [1. Circuit Configuration of Radio Frequency Module 1 and Communication Device 5]

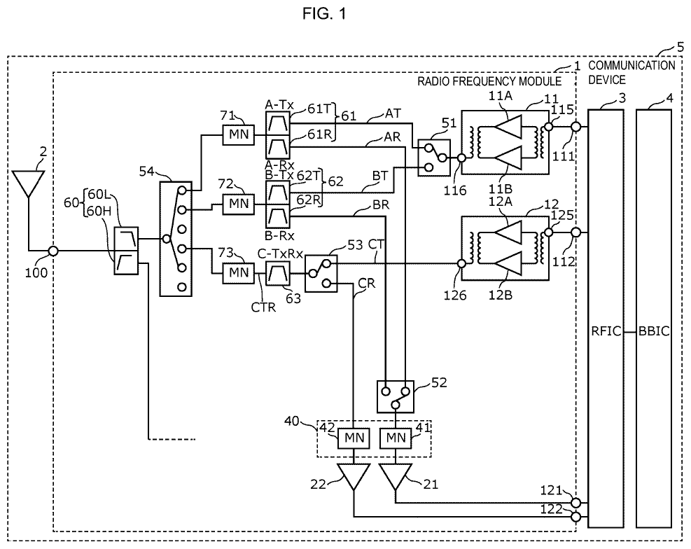

FIG. 1 is a circuit configuration diagram of a radio frequency module 1 and a communication device 5 according to an exemplary embodiment. As illustrated in FIG. 1, the communication device 5 includes the radio frequency module 1, an antenna 2, a radio frequency (RF) signal processing circuit (RFIC) 3, and a baseband signal processing circuit (BBIC) 4.

The RFIC 3 is an RF signal processing circuit that processes radio frequency signals received by the antenna 2. Specifically, the RFIC 3 performs signal processing, such as down-conversion, on a reception signal input through a reception path of the radio frequency module 1, and outputs, to the BBIC 4, the reception signal generated through the signal processing. The RFIC 3 performs signal processing, such as up-conversion, on a transmission signal received from the BBIC 4, and outputs, to a transmission path of the radio frequency module 1, the transmission signal generated through the signal processing.

The BBIC 4 is a circuit that performs signal processing using an intermediate frequency band lower than radio frequency signals that are transmitted through the radio frequency module 1. Signals processed by the BBIC 4 are, for example, used as image signals for image display or as audio signals for calls through speakers.

The RFIC 3 also functions as a controller that controls connection of switches 51, 52, 53, and 54 of the radio frequency module 1 on the basis of a communication band (frequency band) to be used. Specifically, the RFIC 3 switches connection of the switches 51 to 54 of the radio frequency module 1 in accordance with a control signal (not illustrated). Note that the controller may be provided outside the RFIC 3 and may be provided in, for example, the radio frequency module 1 or the BBIC 4.

The antenna 2 is connected to an antenna connection terminal 100 of the radio frequency module 1, radiates radio frequency signals output from the radio frequency module 1, and also receives radio frequency signals from the outside and outputs the radio frequency signals to the radio frequency module 1.

Note that, in the communication device 5 according to the present exemplary embodiment, the antenna 2 and the BBIC 4 are non-essential constituent elements.

Next, a detailed configuration of the radio frequency module 1 will be described.

As illustrated in FIG. 1, the radio frequency module 1 includes the antenna connection terminal 100, power amplifiers 11 and 12, low-noise amplifiers 21 and 22, transmission filters 61T and 62T, reception filters 61R and 62R, a filter 63, a reception input matching circuit 40, matching circuits 71, 72, and 73, the switches 51, 52, 53, and 54, and a diplexer 60.

The antenna connection terminal 100 is an example of an input-output terminal and is a common antenna terminal connected to the antenna 2.

The power amplifier 11 is a differential amplification type amplifier that amplifies radio frequency signals of a band A and a band B belonging to a first frequency band group input from a transmission input terminal 111. The power amplifier 12 is a differential amplification type amplifier that amplifies radio frequency signals of a band C belonging to a second frequency band group input from a transmission input terminal 112, the second frequency band group having different frequencies from the first frequency band group.

The low-noise amplifier 21 is an amplifier that amplifies, with low noise, radio frequency signals of the band A and the band B and outputs the amplified radio frequency signals to a reception output terminal 121. The low-noise amplifier 22 is an amplifier that amplifies, with low noise, radio frequency signals of the band C and outputs the amplified radio frequency signals to a reception output terminal 122.

The transmission filter 61T is disposed along a transmission path AT connecting the power amplifier 11 and the antenna connection terminal 100, and allows transmission signals of a transmission band of the band A among transmission signals amplified by the power amplifier 11 to pass therethrough. The transmission filter 62T is disposed along a transmission path BT connecting the power amplifier 11 and the antenna connection terminal 100, and allows transmission signals of a transmission band of the band B among the transmission signals amplified by the power amplifier 11 to pass therethrough.

The reception filter 61R is disposed along a reception path AR connecting the low-noise amplifier 21 and the antenna connection terminal 100, and allows reception signals of a reception band of the band A among reception signals input from the antenna connection terminal 100 to pass therethrough. The reception filter 62R is disposed along a reception path BR connecting the low-noise amplifier 21 and the antenna connection terminal 100, and allows reception signals of a reception band of the band B among the reception signals input from the antenna connection terminal 100 to pass therethrough.

The transmission filter 61T and the reception filter 61R constitute a duplexer 61, which uses the band A as a pass band. The duplexer 61 transmits transmission signals and reception signals of the band A using a frequency division duplex (FDD) scheme. The transmission filter 62T and the reception filter 62R constitute a duplexer 62, which uses the band B as a pass band. The duplexer 62 transits transmission signals and reception signals of the band B using a FDD scheme.

Note that each of the duplexers 61 and 62 may be a multiplexer constituted only by a plurality of transmission filters, a multiplexer constituted only by a plurality of reception filters, or a multiplexer constituted by a plurality of duplexers.

The filter 63 is disposed along a path connecting the switch 53 and the switch 54, allows transmission signals of the band C among transmission signals amplified by the power amplifier 12 to pass therethrough, and allows reception signals of the band C among the reception signals input from the antenna connection terminal 100 to pass therethrough. The filter 63 transmits, using a time division duplex (TDD) scheme, transmission signals and reception signals of the band C in accordance with the switching operation of the switch 53.

One end of the transmission path AT is connected to the transmission input terminal 111, and the other end of the transmission path AT is connected to the antenna connection terminal 100. One end of the transmission path BT is connected to the transmission input terminal 111, and the other end of the transmission path BT is connected to the antenna connection terminal 100. One end of a transmission path CT is connected to the transmission input terminal 112, and the other end of the transmission path CT is connected to the antenna connection terminal 100.

One end of the reception path AR is connected to the antenna connection terminal 100, and the other end of the reception path AR is connected to the reception output terminal 121. One end of the reception path BR is connected to the antenna connection terminal 100, and the other end of the reception path BR is connected to the reception output terminal 121. One end of a reception path CR is connected to the antenna connection terminal 100, and the other end of the reception path CR is connected to the reception output terminal 122.

One end of a transmission-reception path CTR is connected to the switch 53, and the other end of the transmission-reception path CTR is connected to the antenna connection terminal 100. That is, the transmission-reception path CTR includes part of the transmission path CT and part of the reception path CR.

The reception input matching circuit 40 has matching circuits 41 and 42. The matching circuit 41 is disposed along a reception path connecting the low-noise amplifier 21 and the reception filters 61R and 62R, and achieves impedance matching between the low-noise amplifier 21 and the reception filters 61R and 62R. The matching circuit 42 is disposed along a reception path connecting the low-noise amplifier 22 and the filter 63, and achieves impedance matching between the low-noise amplifier 22 and the filter 63.

The switch 51 has a common terminal and two selection terminals. The common terminal of the switch 51 is connected to an output terminal 116 of the power amplifier 11. One of the selection terminals of the switch 51 is connected to the transmission filter 61T, and the other one of the selection terminals of the switch 51 is connected to the transmission filter 62T. In this connection configuration, the switch 51 switches between connection of the common terminal and the one selection terminal and connection of the common terminal and the other selection terminal. That is, the switch 51 switches between connection of the power amplifier 11 and the transmission filter 61T and connection of the power amplifier 11 and the transmission filter 62T. The switch 51 is constituted by a Single Pole Double Throw (SPDT) switch circuit, for example.

The switch 52 has a common terminal and two selection terminals. The common terminal of the switch 52 is connected to the input terminal of the low-noise amplifier 21 with the matching circuit 41 interposed therebetween. One of the selection terminals of the switch 52 is connected to the reception filter 61R, and the other one of the selection terminals of the switch 52 is connected to the reception filter 62R. In this connection configuration, the switch 52 switches between connection and disconnection of the common terminal and the one selection terminal and between connection and disconnection of the common terminal and the other selection terminal. That is, the switch 52 switches between connection and disconnection of the low-noise amplifier 21 and the reception filter 61R and between connection and disconnection of the low-noise amplifier 21 and the reception filter 62R. The switch 52 is constituted by a SPDT switch circuit, for example.

The switch 53 has a common terminal and two selection terminals. The common terminal of the switch 53 is connected to the filter 63. One of the selection terminals of the switch 53 is connected to an output terminal 126 of the power amplifier 12, and the other one of the selection terminals of the switch 53 is connected to the input terminal of the low-noise amplifier 22 with the matching circuit 42 interposed therebetween. In this connection configuration, the switch 53 switches between connection and disconnection of the common terminal and the one selection terminal and between connection and disconnection of the common terminal and the other selection terminal. That is, the switch 53 switches between connection and disconnection of the filter 63 and the power amplifier 12 and between connection and disconnection of the filter 63 and the low-noise amplifier 22. The switch 53 is constituted by a SPDT switch circuit, for example.

The switch 54 is an example of an antenna switch, is connected to the antenna connection terminal 100 with the diplexer 60 interposed therebetween, and switches between (1) connection of the antenna connection terminal 100 to the transmission path AT and the reception path AR, (2) connection of the antenna connection terminal 100 to the transmission path BT and the reception path BR, and (3) connection of the antenna connection terminal 100 to the transmission-reception path CTR. Note that the switch 54 is constituted by a multi-connection type switch circuit capable of making two or more of the above-described connections (1) to (3) simultaneously.

The matching circuit 71 is disposed along a path connecting the switch 54 and the duplexer 61, and achieves impedance matching between the antenna 2 and switch 54 and the duplexer 61. The matching circuit 72 is disposed along a path connecting the switch 54 and the duplexer 62, and achieves impedance matching between the antenna 2 and switch 54 and the duplexer 62. The matching circuit 73 is disposed along a path connecting the switch 54 and the filter 63, and achieves impedance matching between the antenna 2 and switch 54 and the filter 63.

The diplexer 60 is an example of a multiplexer, and is constituted by filters 60L and 60H. The filter 60L is a filter that treats, as its pass band, a frequency range including the first frequency band group and the second frequency band group. The filter 60H is a filter that treats, as its pass band, a frequency range including other frequency band groups whose frequencies are different from the first frequency band group and the second frequency band group. One terminal of the filter 60L and one terminal of the filter 60H are connected to the antenna connection terminal 100 so as to form a common connection. Each of the filters 60L and 60H is an LC filter including at least one of a chip-shaped inductor and a chip-shaped capacitor, for example. Note that in a case where the first frequency band group and the second frequency band group are located at lower frequencies than the other frequency band groups described above, the filter 60L may be a low-pass filter, and the filter 60H may be a high-pass filter.

Note that the above-described transmission filters 61T and 62T, reception filters 61R and 62R, and filter 63 may each be, for example, any one of acoustic wave filters using surface acoustic waves (SAWs), acoustic wave filters using bulk acoustic waves (BAWs), LC resonant filters, and dielectric filters. Furthermore, the transmission filters 61T and 62T, the reception filters 61R and 62R, and the filter 63 are not limited to these filters.

The matching circuits 41, 42, and 71 to 73 are non-essential constituent elements of the radio frequency module according to the present disclosure.

In the configuration of the radio frequency module 1, the power amplifier 11, the switch 51, the transmission filter 61T, the matching circuit 71, the switch 54, and the filter 60L constitute a first transmission circuit that transmits transmission signals of the band A toward the antenna connection terminal 100. The filter 60L, the switch 54, the matching circuit 71, the reception filter 61R, the switch 52, the matching circuit 41, and the low-noise amplifier 21 constitute a first reception circuit that transmits reception signals of the band A from the antenna 2 through the antenna connection terminal 100.

The power amplifier 11, the switch 51, the transmission filter 62T, the matching circuit 72, the switch 54, and the filter 60L constitute a second transmission circuit that transmits transmission signals of the band B toward the antenna connection terminal 100. The filter 60L, the switch 54, the matching circuit 72, the reception filter 62R, the switch 52, the matching circuit 41, and the low-noise amplifier 21 constitute a second reception circuit that transfers reception signals of the band B from the antenna 2 through the antenna connection terminal 100.

The power amplifier 12, the switch 53, the filter 63, the matching circuit 73, the switch 54, and the filter 60L constitute a third transmission circuit that transmits transmission signals of the band C toward the antenna connection terminal 100. The filter 60L, the switch 54, the matching circuit 73, the filter 63, the switch 53, the matching circuit 42, and the low-noise amplifier 22 constitute a third reception circuit that transmits reception signals of the band C from the antenna 2 through the antenna connection terminal 100.

With the above-described circuit configuration, the radio frequency module 1 can perform at least one of simultaneous transmission, simultaneous reception, and simultaneous transmission and reception on radio frequency signals of either of the communication bands, which are the band A and the band B, and radio frequency signals of the band C.

Note that, in the radio frequency module according to the present disclosure, the above-described three transmission circuits and the above-described three reception circuits are not necessarily connected to the antenna connection terminal 100 with the switch 54 interposed therebetween. The above-described three transmission circuits and the above-described three reception circuits may be connected to the antenna 2 with a different terminal interposed therebetween. Moreover, it is sufficient that the radio frequency module according to the present disclosure include at least one of the first transmission circuit, the second transmission circuit, and the third transmission circuit.

In the radio frequency module according to the present disclosure, it is sufficient that the first transmission circuit include at least the power amplifier 11. Moreover, it is sufficient that the second transmission circuit include at least the power amplifier 11. Moreover, it is sufficient that the third transmission circuit include at least the power amplifier 12.

The low-noise amplifiers 21 and 22 and the switches 51 to 54 may be formed in one semiconductor integrated circuit (IC) 10. Furthermore, the above-described semiconductor IC 10 may further include the power amplifiers 11 and 12. The semiconductor IC 10 is constituted by, for example, a complementary metal-oxide-semiconductor (CMOS). Specifically, the semiconductor IC 10 is formed by a silicon on insulator (SOI) process. This enables the semiconductor IC 10 to be manufactured at a low cost. Note that the semiconductor IC may be constituted by at least one of GaAs, SiGe, and GaN. This makes it possible to output radio frequency signals having high-quality amplification and noise performance.

Next, the circuit configurations of the power amplifiers 11 and 12 will be described in detail.

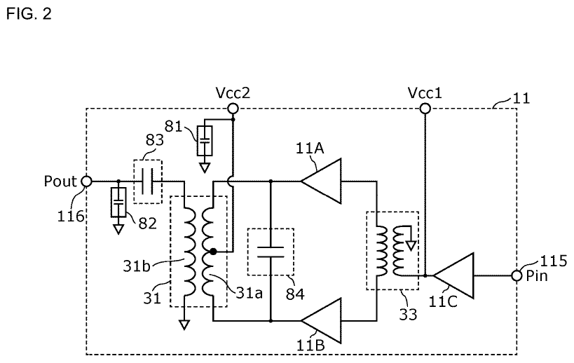

FIG. 2 is a circuit configuration diagram of the power amplifier 11, which is of a differential amplification type, according to the present exemplary embodiment. As illustrated in FIG. 2, the power amplifier 11 includes an input terminal 115 and the output terminal 116, amplification devices 11A (a first amplification device) and 11B (a second amplification device), an amplification device 11C, an output transformer (a transformer) 31, capacitors 81, 82, 83, and 84, and an interstage transformer (an unbalanced-balanced conversion element) 33.

The input terminal of the amplification device 11C is connected to the input terminal 115, and the output terminal of the amplification device 11C is connected to an unbalanced terminal of the interstage transformer 33. One balanced terminal of the interstage transformer 33 is connected to the input terminal of the amplification device 11A, and the other balanced terminal of the interstage transformer 33 is connected to the input terminal of the amplification device 11B.

A radio frequency signal input from the input terminal 115 is amplified by the amplification device 11C in a state where a bias voltage Vcc1 is applied to the amplification device 11C. The amplified radio frequency signal is unbalanced-to-balanced converted by the interstage transformer 33. In this case, a non-inverting input signal is output from the one balanced terminal of the interstage transformer 33, and an inverting input signal is output from the other balanced terminal of the interstage transformer 33.

The output transformer 31 is constituted by a primary coil 31a (a first coil) and a secondary coil 31b (a second coil). One end of the primary coil 31a is connected to the output terminal of the amplification device 11A, and the other end of the primary coil 31a is connected to the output terminal of the amplification device 11B. A bias voltage Vcc2 is applied to a middle point of the primary coil 31a. As a result, the bias voltage Vcc2 is applied to the amplification devices 11A and 11B. One end of the secondary coil 31b is connected to the output terminal 116 with the capacitor 83 interposed therebetween. The other end of the secondary coil 31b is connected to ground. In other words, the output transformer 31 is connected between the output terminals of the amplification devices 11A and 11B and the output terminal 116.

One end of the capacitor 81 is connected to the middle point of the primary coil 31a, and the other end of the capacitor 81 is connected to ground. The capacitor 81 has a function for improving the phase balance and amplitude balance of the non-inverting and inverting input signals flowing through the primary coil 31a. Moreover, the capacitor 81 functions as a bypass capacitor connected to a power supply wiring line and has a function for suppressing the inflow of radio frequency noise into the power supply wiring line and stabilizing the bias voltage Vcc2.

The capacitor 83 is connected to a signal path connecting the one end of the secondary coil 31b and the output terminal 116. Specifically, one end of the capacitor 83 is connected to the one end of the secondary coil 31b, and the other end of the capacitor 83 is connected to the output terminal 116.

The capacitor 82 is connected to the signal path connecting the one end of the secondary coil 31b and the output terminal 116. Specifically, one end of the capacitor 82 is connected to the above-described signal path, and the other end of the capacitor 82 is connected to ground.

The capacitors 82 and 83 function as a matching device that achieves impedance matching between the power amplifier 11 and the switch 51 and transmission filters 61T and 62T, the switch 51 being connected to the output terminal 116.

The capacitor 84 is connected to a point between the output terminal of the amplification device 11A and the output terminal of the amplification device 11B. A non-inverting input signal amplified by the amplification device 11A and an inverting input signal amplified by the amplification device 11B are impedance-converted by the output transformer 31 and the capacitor 84 while maintaining opposite phases.

Each of the capacitors 81 to 84 is a capacitor connected to the output transformer 31.

Note that it is sufficient that the power amplifier 11 according to the present exemplary embodiment include at least one of the capacitors 81 to 84.

With the circuit configuration of the power amplifier 11, the amplification devices 11A and 11B operate in opposite phases. In this case, fundamental currents in the amplification devices 11A and 11B have opposite phases, in other words, flow in opposite directions, so that the fundamental currents do not flow to the ground wiring line and the power supply wiring line that are located substantially equidistant from the amplification devices 11A and 11B. Thus, the unwanted flow of current into the above-described wiring lines can be ignored, so that a power gain reduction that occurs in conventional power amplifiers can be suppressed. Moreover, the non-inverting and inverting signals amplified by the amplification devices 11A and 11B are combined, and thus noise components that are similarly superposed on both signals can be canceled out, and unwanted waves such as harmonic wave components, for example, can be reduced.

Note that the amplification device 11C is a non-essential constituent element of the power amplifier 11. Circuits and structures to convert an unbalanced input signal into a non-inverting input signal and an inverting input signal is not limited to the interstage transformer 33.

The amplification devices 11A, 11B, and 11C are constituted by, for example, field-effect transistors (FETs) or heterojunction bipolar transistors (HBTs) using a Si-based complementary metal oxide semiconductor (CMOS) or GaAs as a material.

Note that the power amplifier 12 includes an input terminal 125 and the output terminal 126, amplification devices 12A and 12B, an amplification device 12C, an output transformer 36, capacitors 86, 87, 88, and 89, and an interstage transformer 38. The circuit configuration of the power amplifier 12 is similar to that of the power amplifier 11 illustrated in FIG. 2.

In this case, in a case where the above-described radio frequency module 1 is mounted on one mounting substrate, the number of circuit elements (the amplification devices 11A to 11C and 12A to 12C, the interstage transformers 33 and 38, the output transformers 31 and 36, and the capacitors 81 to 84 and 86 to 89) constituting the power amplifiers 11 and 12 is large, thereby increasing the size of the radio frequency module 1. In a case where high-density mounting is performed to achieve size reduction, magnetic field coupling, electric field coupling, or electromagnetic field coupling occurs between the output transformers 31 and 36 and other circuit components, so that the magnetic fields generated by the output transformers 31 and 36 are disturbed, thereby causing a problem in that the transmission loss of radio frequency signals that are transmitted through the radio frequency module 1 increases.

In contrast, the radio frequency module 1 according to the present exemplary embodiment has a configuration with which its size is reduced while suppressing magnetic field coupling, electric field coupling, or electromagnetic field coupling between the output transformers 31 and 36 and the other circuit components. In the following, the configuration of the radio frequency module 1 will be described that achieves both suppression of the above-described electric field coupling, the above-described magnetic field coupling, or the electromagnetic field coupling and size reduction.

### [2. Arrangement Configuration of Circuit Elements of Radio Frequency Module 1A According to Example]

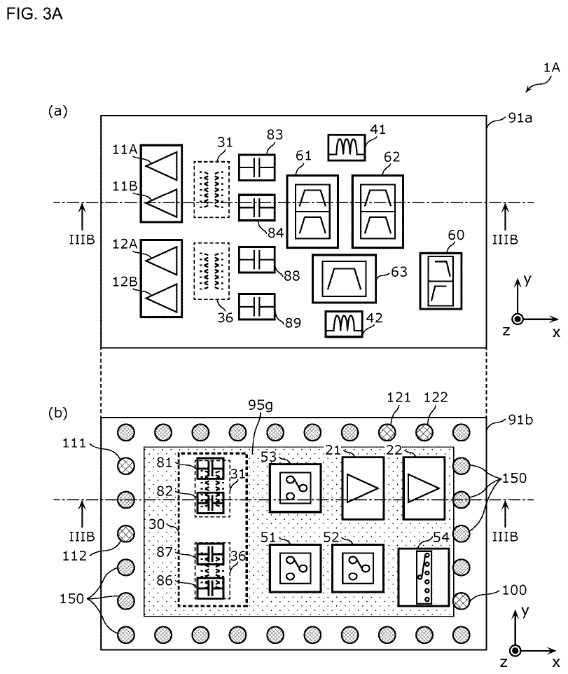

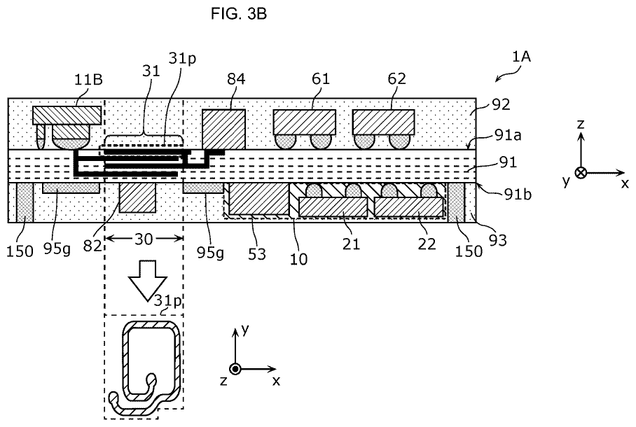

FIG. 3A includes plan views of the radio frequency module 1A according to an example. FIG. 3B is a cross-sectional view of the radio frequency module 1A according to the example, specifically a cross-sectional view taken along line IIIB-IIIB of FIG. 3A. Note that (a) of FIG. 3A illustrates an arrangement diagram of circuit components in a case where, out of main surfaces 91a and 91b of a module substrate 91 that face each other, the main surface 91a is viewed from the positive direction side of the z-axis. In contrast, (b) of FIG. 3A illustrates a perspective view of the arrangement of circuit components in a case where the main surface 91b is viewed from the positive direction side of the z-axis. Moreover, in FIG. 3A, the output transformers 31 and 36 formed inside the module substrate 91 are illustrated by broken lines. Moreover, in FIG. 3A, the circuit components are denoted by marks indicating their functions in order to facilitate understanding the arrangement relationship between the circuit components; however, actual circuit components are not denoted by these marks. Moreover, in FIG. 3A, illustration of wiring lines that connect the module substrate 91 and the individual circuit components is omitted.

The radio frequency module 1A according to the example illustrates a concrete arrangement configuration of the individual circuit elements of the radio frequency module 1 according to the exemplary embodiment.

As illustrated in FIGS. 3A and 3B, the radio frequency module 1A according to the present example further includes the module substrate 91, resin members 92 and 93, and external connection terminals 150 in addition to the circuit configuration illustrated in FIG. 1.

The module substrate 91 has a main surface 91a (a first main surface) and a main surface 91b (a second main surface), which face each other, and is a substrate where the above-described transmission circuits and the above-described reception circuits are mounted. As the module substrate 91, for example, a low temperature co-fired ceramics (LTCC) substrate having a multilayer structure of a plurality of dielectric layers, a high temperature co-fired ceramics (HTCC) substrate, a component built-in substrate, a substrate having a redistribution layer (RDL), a printed circuit board, or the like is used. Note that the antenna connection terminal 100, the transmission input terminals 111 and 112, the reception output terminals 121 and 122, the input terminals 115 and 125, and the output terminals 116 and 126 may be formed on the module substrate 91.

The resin member 92 is disposed on the main surface 91a of the module substrate 91 to cover part of the above-described transmission circuits, part of the above-described reception circuits, and the main surface 91a of the module substrate 91, and has a function for ensuring the reliability of the circuit elements constituting the above-described transmission circuits and the above-described reception circuits, such as mechanical strength and moisture resistance. The resin member 93 is disposed on the main surface 91b of the module substrate 91 to cover part of the above-described transmission circuits, part of the above-described reception circuits, and the main surface 91b of the module substrate 91, and has a function for ensuring the reliability of the circuit elements constituting the above-described transmission circuits and the above-described reception circuits, such as mechanical strength and moisture resistance. Note that the resin members 92 and 93 are non-essential constituent elements of the radio frequency module according to the present disclosure.

As illustrated in FIGS. 3A and 3B, the amplification devices 11A, 11B, 12A, and 12B, the capacitors 83, 84, 88, and 89, the duplexers 61 and 62, the filter 63, the matching circuits 41 and 42, and the diplexer 60 are disposed on the main surface 91a of the module substrate 91 in the radio frequency module 1A according to the present example. In contrast, the low-noise amplifiers 21 and 22, the switches 51, 52, 53, and 54, and the capacitors 81, 82, 86, and 87 are disposed on the main surface 91b of the module substrate 91. The output transformers 31 and 36 are formed inside the module substrate 91. Note that, although not illustrated in FIGS. 3A and 3B, the matching circuits 71 to 73 and the interstage transformers 33 and 38 may be disposed on either of the main surfaces 91a and 91b or may be formed inside the module substrate 91.

Note that, although not illustrated in FIG. 3A, the wiring lines constituting the transmission paths AT, BT, and CT and the reception paths AR, BR, and CR illustrated in FIG. 1 are formed inside the module substrate 91 and on the main surfaces 91a and 91b. Moreover, the above-described wiring lines may each be a bonding wire whose both ends are joined to any of the circuit elements constituting the main surfaces 91a and 91b and the radio frequency module 1A or may also be a terminal, an electrode, or a wiring line formed on the surface of the circuit element of the radio frequency module 1A.

In the present example, the amplification devices 11A, 11B, 12A, and 12B are disposed on the main surface 91a, and the capacitors 81, 82, 86, and 87 are disposed on the main surface 91b. According to this, the amplification devices 11A, 11B, 12A, and 12B and the capacitors 81, 82, 86, and 87 are disposed on both sides of the module substrate 91 with the module substrate 91 interposed therebetween. Thus, compared with a configuration in which the amplification devices 11A, 11B, 12A, and 12B and the capacitors 81, 82, 86, and 87 are all disposed on one side of the module substrate 91, the radio frequency module 1A can be reduced in size.

Moreover, in the radio frequency module 1A according to the present example, the output transformers 31 and 36 are formed inside the module substrate 91 between the main surface 91a and the main surface 91b. According to this, the output transformers 31 and 36 do not have to be disposed on the main surface 91a or the main surface 91b, and thus the area of the radio frequency module 1A is reduced. Note that, in the output transformer 31 formed inside the module substrate 91, the primary coil 31a and the secondary coil 31b are each formed using a planar wiring pattern 31p along the xy-plane direction, for example. The primary coil 31a and the secondary coil 31b, which are formed using the planar wiring pattern 31p, are magnetically coupled to each other in a certain manner by being disposed so as to face each other in the xy-plane or in the z-axis direction.

As illustrated in FIG. 3B, the output transformers 31 and 36 are disposed inside the module substrate 91 and are disposed closer to the main surface 91a out of the main surfaces 91a and 91b. In contrast, as illustrated in (b) of FIG. 3A, the capacitors 81 and 82 are disposed on the main surface 91b, and are disposed so as to overlap the output transformer 31 in a case where the module substrate 91 is viewed in a plan view. Moreover, the capacitors 86 and 87 are disposed on the main surface 91b, and are disposed so as to overlap the output transformer 36 in a case where the module substrate 91 is viewed in a plan view.

According to this, in the above-described plan view, the capacitors 81 and 82 and the output transformer 31 are disposed so as to overlap each other, and the capacitors 86 and 87 and the output transformer 36 are disposed so as to overlap each other, so that the radio frequency module 1A can be reduced in size.

Note that “the output transformer 31 and a circuit component overlap each other in a case where the module substrate 91 is viewed in a plan view” means that a formation region 30 of the output transformer 31 and the circuit component overlap each other in a case where the module substrate 91 is viewed in a plan view.

Whereas the capacitors 81 and 82 are disposed on the main surface 91b, the output transformer 31 is disposed inside the module substrate 91 and on the closer side to the main surface 91a. Thus, the distance between the capacitors 81 and 82 and the output transformer 31 can be secured. Consequently, it becomes possible to suppress magnetic field coupling, electric field coupling, or electromagnetic field coupling between the output transformer 31 and the capacitors 81 and 82, so that the magnetic field generated by the output transformer 31 can be disturbed to a lesser degree, and the transmission loss of transmission signals that pass through the output transformer 31 can be reduced.

Similarly, whereas the capacitors 86 and 87 are disposed on the main surface 91b, the output transformer 36 is disposed inside the module substrate 91 and on the closer side to the main surface 91a. Thus, the distance between the capacitors 86 and 87 and the output transformer 36 can be secured. Consequently, it becomes possible to suppress magnetic field coupling, electric field coupling, or electromagnetic field coupling between the output transformer 36 and the capacitors 86 and 87, so that the magnetic field generated by the output transformer 36 can be disturbed to a lesser degree, and the transmission loss of transmission signals that pass through the output transformer 36 can be reduced.

Note that it is sufficient that the radio frequency module according to the present disclosure satisfy at least one of the following: (1) the output transformer 31 is disposed inside the module substrate 91 and closer to the main surface 91a, and the capacitors 81 and 82 are disposed on the main surface 91b so as to overlap the output transformer 31 in the above-described plan view; and (2) the output transformer 36 is disposed inside the module substrate 91 and closer to the main surface 91a, and the capacitors 86 and 87 are disposed on the main surface 91b so as to overlap the output transformer 36 in the above-described plan view.

Moreover, instead of the capacitors 81, 82, 86, and 87, the capacitors 83, 84, 88, and 89 may be disposed on the main surface 91b so as to overlap at least one of the output transformers 31 and 36 in the above-described plan view. Furthermore, instead of the capacitors 81, 82, 86, and 87, at least one of the capacitors 81 to 84 and 86 to 89 may be disposed on the main surface 91b and may be disposed so as to overlap at least one of the output transformers 31 and 36 in the above-described plan view.

Moreover, the capacitors 83, 84, 88, and 89, the duplexers 61 and 62, the filter 63, the matching circuits 41 and 42, the diplexer 60, the low-noise amplifiers 21 and 22, and the switches 51, 52, 53, and 54 may be disposed on any of the main surfaces 91a and 91b of the module substrate 91 or inside the module substrate 91.

Moreover, in the radio frequency module 1A according to the present example, as illustrated in FIG. 3A, in a case where the module substrate 91 is viewed in a plan view, it is desirable that the amplification devices 11A and 11B do not overlap the output transformer 31 and that the amplification devices 12A and 12B do not overlap the output transformer 36.

Consequently, it becomes possible to suppress unnecessary magnetic field coupling or electromagnetic field coupling between the amplification devices 11A and 11B and the secondary coil 31b of the output transformer 31 and also unnecessary magnetic field coupling or electromagnetic field coupling between the amplification devices 12A and 12B and a secondary coil 36b of the output transformer 36. Thus, it becomes possible to suppress an increase in transmission loss and an increase in the number of unwanted waves resulting from reductions in the impedance matching levels of the power amplifiers 11 and 12.

Moreover, in the radio frequency module 1A according to the present example, a plurality of external connection terminals 150 are disposed on the main surface 91b side of the module substrate 91. The radio frequency module 1A communicates through transmission and reception of electrical signals with an external substrate disposed on the negative direction side of the z-axis with respect to the radio frequency module 1A via the plurality of external connection terminals 150. Moreover, some of the plurality of external connection terminals 150 are set to the ground potential of the external substrate. Not the amplification devices 11A, 11B, 12A, and 12B, which are difficult to reduce in height, but the low-noise amplifiers 21 and 22 and switches 51 to 54, which are easy to reduce in height, are disposed on the main surface 91b facing the external substrate out of the main surfaces 91a and 91b, so that the entirety of the radio frequency module 1A can be reduced in height. Moreover, a plurality of external connection terminals 150 that are used as ground electrodes are disposed around the low-noise amplifiers 21 and 22, which greatly affect the reception sensitivity of the reception circuits, so that a reduction in the reception sensitivity of the reception circuits can be suppressed.

Note that the capacitors 81, 82, 86, and 87 may be semiconductor components. More specifically, the capacitors 81, 82, 86, and 87 are so-called silicon capacitors and may be formed on a silicon substrate (a silicon wafer) through a semiconductor process. Furthermore, the capacitors 81, 82, 86, and 87 may be integrated passive devices (IPD) using silicon substrates. In a case where the capacitors 81, 82, 86, and 87 are semiconductor components or IPDs using silicon substrates, the capacitors 81, 82, 86, and 87 can be made thinner by polishing, so that the main surface 91b side of the module substrate 91 can be reduced in height.

Moreover, the capacitors 81, 82, 86, and 87 may be surface mount devices.

Note that the external connection terminals 150 may be columnar electrodes that penetrate the resin member 93 in the z-axis direction as illustrated in FIGS. 3A and 3B. Alternatively, the external connection terminals 150 may be bump electrodes formed on the main surface 91b. In this case, the resin member 93 on the main surface 91b side may be omitted.

The amplification devices 11A, 11B, 12A, and 12B are components that generate large amounts of heat among the circuit components of the radio frequency module 1A. In order to increase the heat dissipation characteristics of the radio frequency module 1A, it is important to release heat generated by the amplification devices 11A, 11B, 12A, and 12B to the external substrate through a heat dissipation path having a small thermal resistance. If the amplification devices 11A, 11B, 12A, and 12B are mounted on the main surface 91b, electrode wiring lines connected to the amplification devices 11A, 11B, 12A, and 12B are disposed on the main surface 91b. Thus, the heat dissipation path includes a heat dissipation path via only the planar wiring pattern on the main surface 91b (along the xy-plane direction). The planar wiring pattern is formed using a metal thin film, thereby having a large thermal resistance. Thus, in a case where the amplification devices 11A, 11B, 12A, and 12B are disposed on the main surface 91b, the heat dissipation characteristics degrade.

In contrast, as in the present example, in a case where the amplification devices 11A, 11B, 12A, and 12B are mounted on the main surface 91a, through electrodes that penetrate between the main surface 91a and the main surface 91b can connect the amplification devices 11A, 11B, 12A, and 12B and the external connection terminals 150. Thus, as the heat dissipation path for the amplification devices 11A, 11B, 12A, and 12B, heat dissipation paths routed only through the planar wiring line pattern having a large thermal resistance and along the xy-plane direction among the wiring lines within the module substrate 91 can be eliminated. Consequently, the radio frequency module 1A can be provided that is small in size and has improved heat dissipation characteristics from the amplification devices 11A, 11B, 12A, and 12B to the external substrate.

With the above-described configuration for improving the heat dissipation characteristics of the radio frequency module 1A, the through electrodes, external connection terminals, and the like that aim to dissipate heat are disposed in the regions facing the amplification devices 11A, 11B, 12A and 12B in the z-axis direction, so that it is desirable that no circuit components be disposed in the regions. From this point of view, in a case where the module substrate 91 is viewed in a plan view, it is also desirable that the amplification devices 11A and 11B do not overlap the output transformer 31 and that the amplification devices 12A and 12B do not overlap the output transformer 36.

In the radio frequency module 1A according to the present example, as illustrated in FIGS. 3A and 3B, the module substrate 91 has a ground electrode layer 95g formed on the main surface 91b along a direction parallel to the xy-plane direction. In this case, in a case where the module substrate 91 is viewed in a plan view, it is desirable not to form the ground electrode layer 95g in regions located on both the main surface 91a side and the main surface 91b side with respect to the output transformers 31 and 36, the regions overlapping the formation regions 30 of the output transformers 31 and 36.

According to this, since a large distance can be secured between the output transformers 31 and 36 and the ground electrode, the magnetic fields generated by the output transformers 31 and 36 can be disturbed to a lesser degree by the ground electrode, so that the transmission loss of transmission signals that are transmitted through the power amplifiers 11 and 12 can be reduced.

Note that a configuration may be used in which the ground electrode layer 95g is not formed in the regions that overlap the formation regions 30 of the output transformers 31 and 36 on either one out of the main surface 91a side and 91b side. Even in this case, the transmission loss of transmission signals that are transmitted through the power amplifiers 11 and 12 can be reduced.

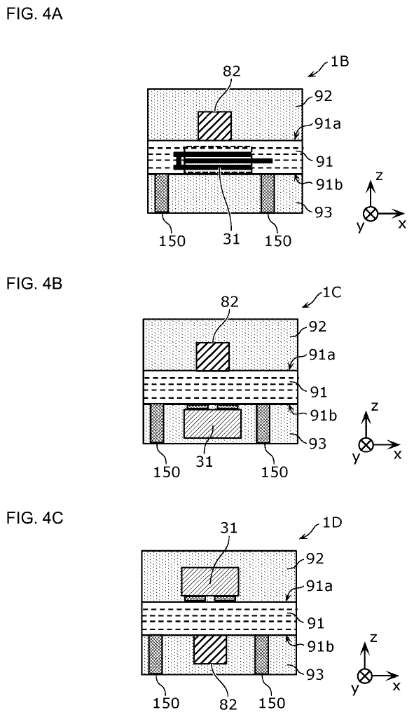

FIG. 4A is a cross-sectional view of a radio frequency module 1B according to a first modification. In FIG. 4A, the arrangement of the output transformer 31 and the capacitor 82 among the circuit components of the radio frequency module 1B according to the first modification is described. Note that the arrangement of the circuit components other than the output transformer 31 and the capacitors 81 and 82 of the radio frequency module 1B is the same as that of the radio frequency module 1A according to the example. In the radio frequency module 1B, the output transformer 31 is disposed inside the module substrate 91 and is formed closer to the main surface 91b out of the main surface 91a and the main surface 91b. In this case, the capacitors 81 and 82 are disposed on the main surface 91a, and are disposed so as to overlap the output transformer 31 in a case where the module substrate 91 is viewed in a plan view.

According to this, the output transformer 31 does not have to be disposed on the main surface 91a or the main surface 91b, and thus the area of the radio frequency module 1B is reduced. Moreover, since the capacitors 81 and 82 and the output transformer 31 are disposed so as to overlap in the above-described plan view, the radio frequency module 1B can be reduced in size. Whereas the capacitors 81 and 82 are disposed on the main surface 91a, the output transformer 31 is disposed inside the module substrate 91 and closer to the main surface 91b. Thus, the distance between the capacitors 81 and 82 and the output transformer 31 can be secured. Consequently, it becomes possible to suppress magnetic field coupling, electric field coupling, or electromagnetic field coupling between the output transformer 31 and the capacitors 81 and 82, so that the magnetic field generated by the output transformer 31 can be disturbed to a lesser degree, and the transmission loss of transmission signals that pass through the output transformer 31 can be reduced.

FIG. 4B is a cross-sectional view of a radio frequency module 1C according to a second modification. In FIG. 4B, the arrangement of the output transformer 31 and the capacitor 82 among the circuit components of the radio frequency module 1C according to the second modification is described. Note that the arrangement of the circuit components other than the output transformer 31 and the capacitors 81 and 82 of the radio frequency module 1C is the same as that of the radio frequency module 1A according to the example. In the radio frequency module 1C, the output transformer 31 is disposed on the main surface 91b. The output transformer 31 is a chip-shaped inductor or the like. In this case, the capacitors 81 and 82 are disposed on the main surface 91a, and are disposed so as to overlap the output transformer 31 in a case where the module substrate 91 is viewed in a plan view.

According to this, since the capacitors 81 and 82 and the output transformer 31 are disposed so as to overlap in the above-described plan view, the radio frequency module 1C can be reduced in size. Whereas the capacitors 81 and 82 are disposed on the main surface 91a, the output transformer 31 is disposed on the main surface 91b. Thus, the distance between the capacitors 81 and 82 and the output transformer 31 can be secured. Consequently, it becomes possible to suppress magnetic field coupling, electric field coupling, or electromagnetic field coupling between the output transformer 31 and the capacitors 81 and 82, so that the magnetic field generated by the output transformer 31 can be disturbed to a lesser degree, and the transmission loss of transmission signals that pass through the output transformer 31 can be reduced.

Note that the output transformer 31 may be a semiconductor component. More specifically, the output transformer 31 may be formed on a silicon substrate (a silicon wafer) through a semiconductor process. Furthermore, the output transformer 31 may be an IPD using a silicon substrate. This enables the output transformer 31 to be made thinner by polishing, so that the main surface 91b side of the module substrate 91 can be reduced in height.

FIG. 4C is a cross-sectional view of a radio frequency module 1D according to a third modification. In FIG. 4C, the arrangement of the output transformer 31 and the capacitor 82 among the circuit components of the radio frequency module 1D according to the third modification is described. Note that the arrangement of the circuit components other than the output transformer 31 and the capacitors 81 and 82 of the radio frequency module 1D is the same as that of the radio frequency module 1A according to the example. In the radio frequency module 1D, the output transformer 31 is disposed on the main surface 91a. The output transformer 31 is a chip-shaped inductor or the like. In this case, the capacitors 81 and 82 are disposed on the main surface 91b, and are disposed so as to overlap the output transformer 31 in a case where the module substrate 91 is viewed in a plan view.

According to this, since the capacitors 81 and 82 and the output transformer 31 are disposed so as to overlap in the above-described plan view, the radio frequency module 1D can be reduced in size. Whereas the capacitors 81 and 82 are disposed on the main surface 91b, the output transformer 31 is disposed on the main surface 91a. Thus, the distance between the capacitors 81 and 82 and the output transformer 31 can be secured. Consequently, it becomes possible to suppress magnetic field coupling, electric field coupling, or electromagnetic field coupling between the output transformer 31 and the capacitors 81 and 82, so that the magnetic field generated by the output transformer 31 can be disturbed to a lesser degree, and the transmission loss of transmission signals that pass through the output transformer 31 can be reduced.

Note that the formation region 30 of the output transformer 31 is defined as follows. In a case where the module substrate 91 is viewed in a plan view, the formation region 30 of the output transformer 31 is the smallest region that includes the formation region of the primary coil 31a and the formation region of the secondary coil 31b.

In this case, the secondary coil 31b is defined as a wiring conductor that is provided along the primary coil 31a and is disposed in a section having a substantially constant distance, which is a first distance, to the primary coil 31a. In this case, the distances from wiring conductors located on both sides of the above-described section to the primary coil 31a are each a second distance that is longer than the first distance, and the one end and the other end of the secondary coil 31b are points where the distances from the wiring conductors to the primary coil 31a change from the first distance to the second distance. The primary coil 31a is defined as a wiring conductor that is provided along the secondary coil 31b and is disposed in a section having a substantially constant distance, which is the first distance, to the secondary coil 31b. In this case, the distances from wiring conductors located on both sides of the above-described section to the secondary coil 31b are each the second distance that is longer than the first distance, and the one end and the other end of the primary coil 31a are points where the distances from the wiring conductors to the secondary coil 31b change from the first distance to the second distance.

Alternatively, the secondary coil 31b is defined as a wiring conductor that is provided along the primary coil 31a and is disposed in a first section having a substantially constant line width, which is a first width. The primary coil 31a is defined as a wiring conductor that is provided along the secondary coil 31b and is disposed in the first section having a substantially constant line width, which is the first width.

Alternatively, the secondary coil 31b is defined as a wiring conductor that is provided along the primary coil 31a and is disposed in a first section having a substantially constant film thickness, which is a first film thickness. The primary coil 31a is defined as a wiring conductor that is provided along the secondary coil 31b and is disposed in the first section having a substantially constant film thickness, which is the first film thickness.

Alternatively, the secondary coil 31b is defined as a wiring conductor that is provided along the primary coil 31a and is disposed in a first section having a substantially constant level of coupling, which is a first level of coupling, to the primary coil 31a. The primary coil 31a is defined as a wiring conductor that is provided along the secondary coil 31b and is disposed in the first section having a substantially constant level of coupling, which is the first level of coupling, to the secondary coil 31b.

“In a case where the output transformer 31 is formed inside the module substrate 91, the output transformer 31 is disposed closer to the main surface 91a out of the main surface 91a and the main surface 91b” means that the distance between the center point of the output transformer 31 in the vertical direction (the z-axis direction) of the module substrate 91 and the main surface 91a is shorter than the distance between the center point and the main surface 91b.

### [3. Circuit Configuration of Radio Frequency Module 1E According to Fourth Modification]

Whereas the radio frequency module 1 according to the example includes the power amplifiers 11 and 12, which are differential amplification type amplifiers, a radio frequency module 1E according to a fourth modification includes power amplifiers 13 and 14, which are Doherty amplifiers, instead of the power amplifiers 11 and 12, which are differential amplification type amplifiers. That is, in the radio frequency module 1E according to the present modification, the power amplifier 13 is disposed instead of the power amplifier 11, and the power amplifier 14 is disposed instead of the power amplifier 12 in the circuit configuration of the radio frequency module 1 illustrated in FIG. 1.

Next, the circuit configurations of the power amplifiers 13 and 14 will be described in detail.

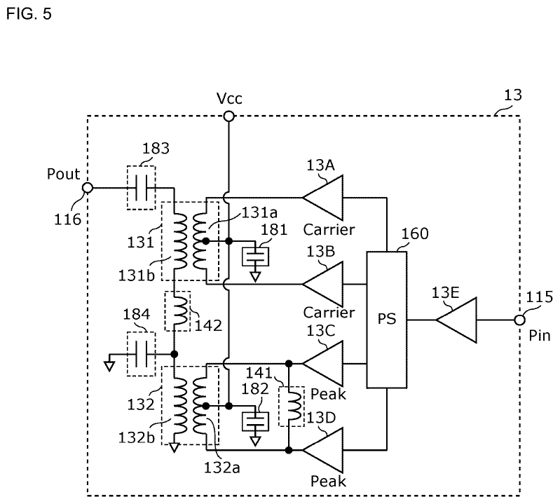

FIG. 5 is a circuit configuration diagram of the power amplifier 13, which is a Doherty amplifier, according to the fourth modification. As illustrated in FIG. 5, the power amplifier 13 includes the input terminal 115 and the output terminal 116, amplification devices 13A (a first amplification device) and 13B (a second amplification device), amplification devices 13C (a first amplification device) and 13D (a second amplification device), an amplification device 13E, output transformers (transformers) 131 and 132, capacitors 181, 182, 183, and 184, inductors 141 and 142, and a phase shift circuit 160.

The power amplifier 13 amplifies radio frequency signals of the band A, the band B, or the bands A and B input from the input terminal 115.

The phase shift circuit 160 distributes a signal output from the amplification device 13E to the respective amplification devices 13A, 13B, 13C, and 13D. In this case, the phase shift circuit 160 adjusts the phases of the distributed signals. For example the phase shift circuit 160 shifts a signal to be output to the amplification device 13A by +90 degrees (advances the signal by 90 degrees) relative to the signal output from the amplification device 13E, shifts a signal to be output to the amplification device 13B by −90 degrees (delays the signal by 90 degrees) relative to the signal output from the amplification device 13E, shifts a signal to be output to the amplification device 13C by 0 degrees (does not shift the signal) relative to the signal output from the amplification device 13E, and shifts a signal to be output to the amplification device 13D by +180 degrees (advances the signal by 180 degrees) relative to the signal output from the amplification device 13E.

Note that the configurations of the amplification device 13E and the phase shift circuit 160 are not limited to those described above. For example, the amplification device 13E may be disposed upstream of each of the amplification devices 13A to 13D. In this case, the phase shift circuit 160 may be disposed upstream of each of the pre-amplifiers or each of the respective amplification devices 13A to 13D. Moreover, the power amplifier 13 does not have to include the amplification device 13E or the phase shift circuit 160.

Each of the amplification devices 13A to 13D includes an amplification transistor. The above-described amplification transistor is, for example, a bipolar transistor such as a heterojunction bipolar transistor (HBT) or a field-effect transistor such as a metal oxide semiconductor field-effect transistor (MOSFET).

The amplification devices 13A and 13B are an example of the first amplification device and an example of the second amplification device, respectively, and are class A (or AB) amplification circuits that can perform amplification operation on all power levels of input signals and can efficiently perform amplification operation on especially low and medium power regions. The amplification devices 13A and 13B are, for example, carrier amplifiers.

The amplification devices 13C and 13D are an example of the first amplification device and an example of the second amplification device, respectively, and are, for example, class C amplification circuits that can perform amplification operation on the high power level region of input signals. Lower bias voltages are applied to the amplification transistors of the amplification devices 13C and 13D than to the amplification transistors of the amplification devices 13A and 13B, and thus the higher the input signal power level, the lower the output impedance. This enables the amplification devices 13C and 13D to perform a low-distortion amplification operation in the high power region. The amplification devices 13C and 13D are, for example, peak amplifiers.

The output transformer 131 includes a primary coil 131a and a secondary coil 131b. One end of the primary coil 131a is connected to the output terminal of the amplification device 13A, and the other end of the primary coil 131a is connected to the output terminal of the amplification device 13B. A bias voltage Vcc is applied to a middle point of the primary coil 131a. As a result, the bias voltage Vcc is applied to the amplification devices 13A and 13B. One end of the secondary coil 131b is connected to the output terminal 116 with the capacitor 183 interposed therebetween, and the other end of the secondary coil 131b is connected to one end of a secondary coil 132b with the inductor 142 interposed therebetween.

The output transformer 132 includes a primary coil 132a and the secondary coil 132b. One end of the primary coil 132a is connected to the output terminal of the amplification device 13C, and the other end of the primary coil 132a is connected to the output terminal of the amplification device 13D. The bias voltage Vcc is applied to a middle point of the primary coil 132a. As a result, the bias voltage Vcc is applied to the amplification devices 13C and 13D. The other end of the secondary coil 132b is connected to ground.

With the above-described connection configuration of the output transformers 131 and 132, the differential signals output from the amplification devices 13A and 13B and the differential signals output from the amplification devices 13C and 13D are added together with respect to their voltages, and the combined output signal is output from the output terminal 116.

The inductor 141 is connected between the output terminal of the amplification device 13C and the output terminal of the amplification device 13D, and has a function for adjusting the phases of transmission signals output from the amplification devices 13C and 13D relative to the signals output from the amplification devices 13A and 13B.

One end of the capacitor 181 is connected to the middle point of the primary coil 131a, and the other end of the capacitor 181 is connected to ground. The capacitor 181 has a function for improving the phase balance and amplitude balance of the non-inverting and inverting input signals flowing through the primary coil 131a. Moreover, the capacitor 181 functions as a bypass capacitor connected to the power supply wiring line and has a function for suppressing the inflow of radio frequency noise into the power supply wiring line and stabilizing the bias voltage Vcc. One end of the capacitor 182 is connected to the middle point of the primary coil 132a, and the other end of the capacitor 182 is connected to ground. The capacitor 182 has a function for improving the phase balance and amplitude balance of the non-inverting and inverting input signals flowing through the primary coil 132a. Moreover, the capacitor 182 functions as a bypass capacitor connected to the power supply wiring line and has a function for suppressing the inflow of radio frequency noise into the power supply wiring line and stabilizing the bias voltage Vcc.

The capacitor 183 is connected to the signal path connecting the one end of the secondary coil 131b and the output terminal 116. Specifically, one end of the capacitor 183 is connected to the one end of the secondary coil 131b, and the other end of the capacitor 183 is connected to the output terminal 116. The capacitor 184 is connected to the signal path connecting the one end of the secondary coil 132b and ground. Specifically, one end of the capacitor 184 is connected to the one end of the secondary coil 132b, and the other end of the capacitor 184 is connected to ground.

The capacitors 183 and 184 function as a matching device that achieves impedance matching between the power amplifier 13 and the switch 51 and transmission filters 61T and 62T, the switch 51 being connected to the output terminal 116.

Each of the capacitors 181 to 184 is a capacitor connected to the output transformer 131 or 132.

Note that it is sufficient that the power amplifier 13 according to the present exemplary embodiment include at least one of the capacitors 181 to 184.

With the circuit configuration of the power amplifier 13, the output impedance of the amplification devices 13A and 13B at the time when a small signal is input is twice as high as that at the time when a large signal is input. That is, when a small signal is input, the amplification devices 13C and 13D are in the OFF state, and the output impedance of the amplification devices 13A and 13B is increased. Thus, it becomes possible for the power amplifier 13 to perform operation with high efficiency.

In contrast, when a large signal is input, the amplification device 13A to 13D operate, so that a large power signal can be output. In addition, the low output impedance of the amplification devices 13C and 13D enables to suppress signal distortion.

Note that the power amplifier 14 includes the input terminal 125 and the output terminal 126, amplification devices 14A (a first amplification device) and 14B (a second amplification device), amplification devices 14C (a first amplification device) and 14D (a second amplification device), an amplification device 14E, output transformers (transformers) 136 and 137, capacitors 186, 187, 188, and 189, inductors 146 and 147, and a phase shift circuit 165. The circuit configuration of the power amplifier 14 is similar to that of the power amplifier 13 illustrated in FIG. 5.

Note that the power amplifiers 13 and 14, which are Doherty amplifiers, are not limited to the circuit configuration including four amplification devices and two output transformers as described above. For example, the power amplifiers 13 and 14 may have a circuit configuration including one carrier amplifier, one peak amplifier, and one output transformer or a circuit configuration including two or more carrier amplifiers, two or more peak amplifiers, and two or more output transformers.

### [4. Arrangement Configuration of Circuit Elements of Radio Frequency Module 1E According to Fourth Modification]

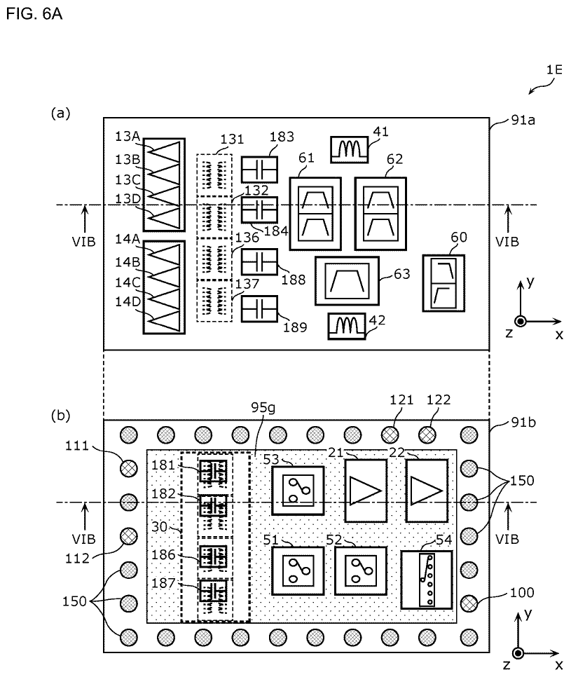

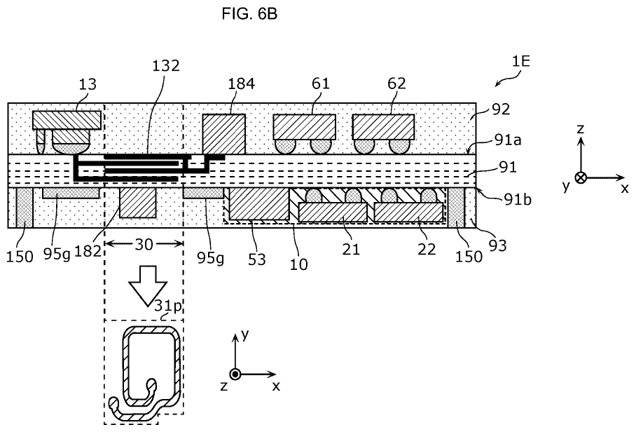

FIG. 6A includes plan views of the radio frequency module 1E according to the fourth modification. FIG. 6B is a cross-sectional view of the radio frequency module 1E according to the modification, specifically a cross-sectional view taken along line VIB-VIB of FIG. 6A. Note that (a) of FIG. 6A illustrates an arrangement diagram of circuit components in a case where, out of the main surfaces 91a and 91b of the module substrate 91 that face each other, the main surface 91a is viewed from the positive direction side of the z-axis. In contrast, (b) of FIG. 6A illustrates a perspective view of the arrangement of circuit components in a case where the main surface 91b is viewed from the positive direction side of the z-axis. Moreover, in FIG. 6A, the output transformers 131, 132, 136, and 137 formed inside the module substrate 91 are illustrated by broken lines. Moreover, in FIG. 6A, the circuit components are denoted by marks indicating their functions in order to facilitate understanding the arrangement relationship between the circuit components; however, actual circuit components are not denoted by these marks. Moreover, in FIG. 6A, illustration of wiring lines that connect the module substrate 91 and the individual circuit components is omitted.

As illustrated in FIGS. 6A and 6B, the radio frequency module 1E according to the present modification includes, instead of the power amplifier 11 and the power amplifier 12 in the circuit configuration illustrated in FIG. 1, the power amplifier 13 and the power amplifier 14, respectively, and further includes the module substrate 91, the resin members 92 and 93, and the external connection terminals 150.

The radio frequency module 1E according to the present modification differs from the radio frequency module 1A according to the example only in terms of the mounting configuration of the power amplifiers 13 and 14. In the following, the radio frequency module 1E according to the present modification will be described mainly about differences from the radio frequency module 1A according to the example, and description of the points that are the same as those of the radio frequency module 1A according to the example will be omitted.

As illustrated in FIGS. 6A and 6B, in the radio frequency module 1E according to the present modification, the amplification devices 13A to 13D and 14A to 14D, the capacitors 183, 184, 188, and 189, the duplexers 61 and 62, the filter 63, the matching circuits 41 and 42, and the diplexer 60 are disposed on the main surface 91a of the module substrate 91. In contrast, the low-noise amplifiers 21 and 22, the switches 51, 52, 53, and 54, and the capacitors 181, 182, 186, and 187 are disposed on the main surface 91b of the module substrate 91. The output transformers 131, 132, 136, and 137 are formed inside the module substrate 91.

In the present example, the amplification devices 13A to 13D and 14A to 14D are disposed on the main surface 91a, and the capacitors 181, 182, 186, and 187 are disposed on the main surface 91b. According to this, the amplification devices 13A to 13D and 14A to 14D and the capacitors 181, 182, 186, and 187 are disposed on both sides of the module substrate 91 with the module substrate 91 interposed therebetween. Thus, compared with a configuration in which the amplification devices 13A to 13D and 14A to 14D and the capacitors 181, 182, 186, and 187 are all disposed on one side of the module substrate 91, the radio frequency module 1E can be reduced in size.

Moreover, in the radio frequency module 1E according to the present example, the output transformers 131, 132, 136, and 137 are formed inside the module substrate 91. According to this, the output transformers 131, 132, 136, and 137 do not have to be disposed on the main surface 91a or the main surface 91b, and thus the area of the radio frequency module 1E is reduced.

As illustrated in FIG. 6B, the output transformers 131, 132, 136, and 137 are disposed inside the module substrate 91 and are disposed closer to the main surface 91a out of the main surfaces 91a and 91b. In contrast, as illustrated in (b) of FIG. 6A, the capacitors 181 and 182 are each disposed on the main surface 91b, and are disposed so as to overlap the output transformers 131 and 132 in a case where the module substrate 91 is viewed in a plan view. Moreover, the capacitors 186 and 187 are each disposed on the main surface 91b, and are disposed so as to overlap the output transformers 136 and 137 in a case where the module substrate 91 is viewed in a plan view.

According to this, in the above-described plan views, the capacitor 181 and the output transformer 131 are disposed so as to overlap each other, the capacitor 182 and the output transformer 132 are disposed so as to overlap each other, the capacitor 186 and the output transformer 136 are disposed so as to overlap each other, and the capacitor 187 and the output transformer 137 are disposed so as to overlap each other, so that the radio frequency module 1E can be reduced in size.

Whereas the capacitors 181 and 182 are disposed on the main surface 91b, the output transformers 131 and 132 are disposed inside the module substrate 91 and closer to the main surface 91a. Thus, the distance between the capacitors 181 and 182 and the output transformers 131 and 132 can be secured. Consequently, it becomes possible to suppress magnetic field coupling, electric field coupling, or electromagnetic field coupling between the output transformers 131 and 132 and the capacitors 181 and 182, so that the magnetic fields generated by the output transformers 131 and 132 can be disturbed to a lesser degree, and the transmission loss of transmission signals that pass through the output transformers 131 and 132 can be reduced.

Similarly, whereas the capacitors 186 and 187 are disposed on the main surface 91b, the output transformers 136 and 137 are disposed inside the module substrate 91 and closer to the main surface 91a. Thus, the distance between the capacitors 186 and 187 and the output transformers 136 and 137 can be secured. Consequently, it becomes possible to suppress magnetic field coupling, electric field coupling, or electromagnetic field coupling between the output transformers 136 and 137 and the capacitors 186 and 187, so that the magnetic fields generated by the output transformers 136 and 137 can be disturbed to a lesser degree, and the transmission loss of transmission signals that pass through the output transformers 136 and 137 can be reduced.

Note that it is sufficient that a radio frequency module according to the present disclosure satisfy at least one of the following: (1) the output transformer 131 is disposed inside the module substrate 91 and closer to the main surface 91a, and the capacitor 181 is disposed on the main surface 91b so as to overlap the output transformer 131 in the above-described plan view; (2) the output transformer 132 is disposed inside the module substrate 91 and closer to the main surface 91a, and the capacitor 182 is disposed on the main surface 91b so as to overlap the output transformer 132 in the above-described plan view; (3) the output transformer 136 is disposed inside the module substrate 91 and closer to the main surface 91a, and the capacitor 186 is disposed on the main surface 91b so as to overlap the output transformer 136 in the above-described plan view; and (4) the output transformer 137 is disposed inside the module substrate 91 and closer to the main surface 91a, and the capacitor 187 is disposed on the main surface 91b so as to overlap the output transformer 137 in the above-described plan view.

Instead of the capacitors 181, 182, 186, and 187, the capacitors 183, 184, 188, and 189 may be disposed on the main surface 91b and may be disposed so as to overlap the output transformers 131, 132, 136, and 137, respectively, in the above-described plan view. Furthermore, instead of the capacitors 181, 182, 186, and 187, at least one of the capacitors 181 to 184 and 186 to 189 may be disposed on the main surface 91b and may be disposed so as to overlap at least one of the output transformers 131, 132, 136, and 137 in the above-described plan view.

The capacitors 183, 184, 188, and 189, the duplexers 61 and 62, the filter 63, the matching circuits 41 and 42, the diplexer 60, the low-noise amplifiers 21 and 22, and the switches 51, 52, 53, and 54 may be disposed on any of the main surfaces 91a and 91b of the module substrate 91 or inside the module substrate 91.

Moreover, in the radio frequency module 1E according to the present modification, as illustrated in FIG. 6A, in a case where the module substrate 91 is viewed in a plan view, it is desirable that the amplification devices 13A and 13B do not overlap the output transformer 131, that the amplification devices 13C and 13D do not overlap the output transformer 132, that the amplification devices 14A and 14B do not overlap the output transformer 136, and that the amplification devices 14C and 14D do not overlap the output transformer 137.

Consequently, it becomes possible to suppress unnecessary magnetic field coupling or electromagnetic field coupling between the amplification devices 13A to 13D and 14A to 14D and the secondary coils of the output transformers 131, 132, 136, and 137. Thus, it becomes possible to suppress an increase in transmission loss and an increase in the number of unwanted waves resulting from reductions in the impedance matching levels of the power amplifiers 13 and 14.

Note that the capacitors 181, 182, 186, and 187 may be semiconductor components. More specifically, the capacitors 181, 182, 186, and 187 are so-called silicon capacitors and may be formed on a silicon substrate (a silicon wafer) through a semiconductor process. Furthermore, the capacitors 181, 182, 186, and 187 may be IPDs using silicon substrates. In a case where the capacitors 181, 182, 186, and 187 are semiconductor components or IPDs using silicon substrates, the capacitors 181, 182, 186, and 187 can be made thinner by polishing, so that the main surface 91b side of the module substrate 91 can be reduced in height.

The capacitors 181, 182, 186, and 187 may be surface mount devices.

Moreover, in the radio frequency module 1E according to the present modification, as illustrated in FIGS. 6A and 6B, the module substrate 91 has a ground electrode layer 95g formed on the main surface 91b along a direction parallel to the xy-plane direction. In this case, in a case where the module substrate 91 is viewed in a plan view, it is desirable not to form the ground electrode layer 95g in regions located on both the main surface 91a side and the main surface 91b side with respect to the output transformers 131, 132, 136, and 137, the regions overlapping the formation regions 30 of the output transformers 131, 132, 136, and 137.

According to this, since a large distance can be secured between the output transformers 131, 132, 136, and 137 and the ground electrode, the magnetic fields generated by the output transformers 131, 132, 136, and 137 can be disturbed to a lesser degree by the ground electrode, so that the transmission loss of transmission signals that are transmitted through the power amplifiers 13 and 14 can be reduced.

Note that a configuration may be used in which the ground electrode layer 95g is not formed in regions that overlap the formation regions 30 of the output transformers 131, 132, 136, and 137 on either one out of the main surface 91a side and 91b side. Even in this case, the transmission loss of transmission signals that are transmitted through the power amplifiers 13 and 14 can be reduced.

The output transformer 131 may be disposed inside the module substrate 91 and be formed closer to the main surface 91b out of the main surface 91a and the main surface 91b, and the capacitor 181 may be disposed on the main surface 91a and be disposed so as to overlap the output transformer 131 in a case where the module substrate 91 is viewed in a plan view.

Moreover, the output transformer 131 may be disposed in or on the main surface 91b, and the capacitor 181 may be disposed on the main surface 91a and be disposed so as to overlap the output transformer 131 in a case where the module substrate 91 is viewed in a plan view.

Moreover, the output transformer 131 may be disposed in or on the main surface 91a, and the capacitor 181 may be disposed on the main surface 91b and be disposed so as to overlap the output transformer 131 in a case where the module substrate 91 is viewed in a plan view.

Even in these cases, since the capacitor 181 and the output transformer 131 are disposed so as to overlap each other, while reducing the size of the radio frequency module 1E, the transmission loss of transmission signals that pass through the output transformer 131 can be reduced.

### [5. Effects and so Forth]

As described above, the radio frequency module 1 according to the exemplary embodiment includes the module substrate 91 with the main surfaces 91a and 91b, which face each other, and the power amplifier 11, which amplifies transmission signals. The power amplifier 11 includes the amplification devices 11A and 11B, the output transformer 31, which includes the primary coil 31a and the secondary coil 31b, and the capacitor 81 connected to the output transformer 31. One end of the primary coil 31a is connected to the output terminal of the amplification device 11A. The other end of the primary coil 31a is connected to the output terminal of the amplification device 11B. One end of the secondary coil 31b is connected to the output terminal 116. The output transformer 31 is disposed in or on the module substrate 91 and is disposed closer to one out of the main surfaces 91a and 91b. The capacitor 81 is disposed in or on the other one out of the main surfaces 91a and 91b and is disposed so as to overlap the output transformer 31 in a case where the module substrate 91 is viewed in a plan view.

According to this, since the capacitor 81 and the output transformer 31 are disposed so as to overlap in the above-described plan view, the radio frequency module 1A can be reduced in size. Whereas the capacitor 81 is disposed on the other one out of the main surfaces 91a and 91b, the output transformer 31 is disposed closer to the one out of the main surfaces 91a and 91b. Thus, the distance between the capacitor 81 and the output transformer 31 can be secured. Consequently, it becomes possible to suppress magnetic field coupling, electric field coupling, or electromagnetic field coupling between the output transformer 31 and the capacitor 81, so that the magnetic field generated by the output transformer 31 can be disturbed to a lesser degree, and the transmission loss of transmission signals that pass through the output transformer 31 can be reduced.

Moreover, for example, the one end of the capacitor 81 may be connected to the middle point of the primary coil 31a, and the other end of the capacitor 81 may be connected to ground in the radio frequency module 1.

According to this, the capacitor 81 functions as a center tap capacitor that improves the phase balance and amplitude balance of balanced signals flowing through the primary coil 31a and as a bypass capacitor that is connected to the power supply line.

Moreover, for example, the capacitor 82 or 83 may be connected to the signal path connecting the one end of the secondary coil 31b and the output terminal 116 in the radio frequency module 1.

According to this, the capacitors 82 and 83 function as a matching device that achieves impedance matching between the power amplifier 11 and the switch 51 and transmission filters 61T and 62T, the switch 51 being connected to the output terminal 116.

Moreover, for example, the output transformer 31 may be formed inside the module substrate 90 in the radio frequency module 1.

According to this, the output transformer 31 does not have to be disposed on the main surface 91a or the main surface 91b, and thus the area of the radio frequency module 1 is reduced.

Moreover, for example, the output transformer 31 may be disposed on the main surface 91a, and the capacitor 81 may be disposed on the main surface 91b in the radio frequency module 1.

According to this, since the capacitor 81 and the output transformer 31 are disposed so as to overlap each other, while reducing the size of the radio frequency module 1, the transmission loss of transmission signals that pass through the output transformer 31 can be reduced.

Moreover, for example, the output transformer 31 may be disposed on the main surface 91b, and the capacitor 81 may be disposed on the main surface 91a in the radio frequency module 1.

According to this, since the capacitor 81 and the output transformer 31 are disposed so as to overlap each other, while reducing the size of the radio frequency module 1, the transmission loss of transmission signals that pass through the output transformer 31 can be reduced.

Moreover, for example, the external connection terminals 150 may be disposed on the main surface 91b, the output transformer 31 may be disposed on the surface of or inside the module substrate 91 and be disposed closer to the main surface 91a out of the main surfaces 91a and 91b, and the capacitor 81 may be disposed on the main surface 91b in the radio frequency module 1.

According to this, since the capacitor 81 and the output transformer 31 are disposed so as to overlap each other, while reducing the size of the radio frequency module 1, the transmission loss of transmission signals that pass through the output transformer 31 can be reduced.

Moreover, for example, the amplification devices 11A and 11B may be disposed on the main surface 91a in the radio frequency module 1.

According to this, heat dissipation characteristics from the amplification devices 11A and 11B to the external substrate can be improved.

Moreover, for example, the capacitor 81 may be a surface mount device in the radio frequency module 1.

Moreover, for example, the capacitor 81 may be a semiconductor component in the radio frequency module 1.

According to this, the capacitor 81 can be made thinner by polishing, so that the radio frequency module 1 can be reduced in height.

Moreover, for example, the power amplifier 11 may be a differential amplification type amplifier in the radio frequency module 1.

Moreover, for example, the amplification devices 13A and 13B may be carrier amplifiers, the amplification devices 13C and 13D may be peak amplifiers, and the power amplifier 13 may be a Doherty amplifier in the radio frequency module 1E.

Moreover, for example, the module substrate 91 may include the ground electrode layer 95g formed along the direction parallel to the main surface 91a or 91b in the radio frequency module 1, and the ground electrode layer 95g does not have to be formed in the region that overlaps the output transformer 31 in a case where the module substrate 91 is viewed in a plan view.

According to this, since a large distance can be secured between the output transformer 31 and the ground electrode, the magnetic field generated by the output transformer 31 can be disturbed to a lesser degree by the ground electrode, so that the transmission loss of transmission signals that are transmitted through the power amplifier 11 can be reduced.

The communication device 5 includes the RFIC 3, which processes radio frequency signals, and the radio frequency module 1A, which transmits radio frequency signals between the RFIC 3 and the antenna 2.

According to this, the effects of the radio frequency module 1A can be realized by the communication device 5.

### Other Embodiments and so Forth

In the description above, the radio frequency modules and the communication device according to the exemplary embodiments of the present disclosure have been described using the exemplary embodiments, examples, and modifications; however, the radio frequency modules and communication device according to the present disclosure are not limited to the above-described exemplary embodiments, examples, and modifications. The present disclosure also includes other exemplary embodiments realized by combining any of the constituent elements of the above-described exemplary embodiments, examples, and modifications, modifications that are obtained by making various changes conceived by those skilled in the art to the above-described exemplary embodiments, examples, and modifications within the scope that does not depart from the gist of the present disclosure, and various devices incorporating the above-described radio frequency modules and communication device.

For example, in the radio frequency modules and communication device according to the above-described exemplary embodiments, examples, and modifications, additional circuit elements and additional wiring lines may be inserted along paths connecting the individual circuit elements and the individual signal paths disclosed in the drawings.

### INDUSTRIAL APPLICABILITY

The present disclosure can be widely used as a radio frequency module in communication devices such as cellular phones, the radio frequency module being disposed in a multi-band front end section.

### REFERENCE SIGNS LIST

1, 1A, 1B, 1C, 1D, 1E radio frequency module
2 antenna
3 RF signal processing circuit (RFIC)
4 baseband signal processing circuit (BBIC)
5 communication device
10 semiconductor IC
11, 12, 13, 14 power amplifier
11A, 11B, 11C, 12A, 12B, 12C, 13A, 13B, 13C, 13D, 13E, 14A, 14B, 14C, 14D, 14E amplification device
21, 22 low-noise amplifier
30 formation region
31, 36, 131, 132, 136, 137 output transformer
31a, 131a, 132a primary coil
31b, 36b, 131b, 132b secondary coil
31p planar wiring pattern
33, 38 interstage transformer
40 reception input matching circuit
41, 42, 71, 72, 73 matching circuit
51, 52, 53, 54 switch
60 diplexer
60H, 60L filter
61, 62 duplexer
61R, 62R reception filter
61T, 62T transmission filter
63 filter
81, 82, 83, 84, 86, 87, 88, 89, 181, 182, 183, 184, 186, 187, 188, 189 capacitor
91 module substrate
91a, 91b main surface
92, 93 resin member
95g ground electrode layer
100 antenna connection terminal
111, 112 transmission input terminal
115, 125 input terminal
116, 126 output terminal
121, 122 reception output terminal
141, 142, 146, 147 inductor
150 external connection terminal
160, 165 phase shift circuit

1. A radio frequency module comprising:
a module substrate including a first main surface that faces a second main surface; and
a power amplifier that amplifies a transmission signal and includes
a first amplification device and a second amplification device,
an output transformer including a first coil and a second coil, and
a capacitor connected to the output transformer, wherein
one end of the first coil is connected to an output terminal of the first amplification device, another end of the first coil is connected to an output terminal of the second amplification device, and one end of the second coil is connected to an output terminal of the power amplifier,
the output transformer is disposed in or on the module substrate and is disposed closer to one of the first main surface and the second main surface than to an other of the first main surface and the second main surface, and
the capacitor is disposed in or on the other of the first main surface and the second main surface, and is disposed to overlap the output transformer in a case where the module substrate is viewed in a plan view.

2. The radio frequency module according to claim 1, wherein
one end of the capacitor is connected to a middle point of the first coil, and another end of the capacitor is connected to ground.

3. The radio frequency module according to claim 1, wherein
the capacitor is connected to a signal path connecting the one end of the second coil and the output terminal of the power amplifier.

4. The radio frequency module according to claim 1, wherein
the output transformer is formed inside the module substrate.

5. The radio frequency module according to claim 1, wherein
the output transformer is disposed on the first main surface, and
the capacitor is disposed on the second main surface.

6. The radio frequency module according to claim 1, wherein
the output transformer is disposed on the second main surface, and
the capacitor is disposed on the first main surface.

7. The radio frequency module according to claim 1, wherein
an external connection terminal is disposed in or on the second main surface,
the output transformer is disposed on a surface of or inside the module substrate, and is disposed closer to the first main surface than the second main surface, and
the capacitor is disposed on the second main surface.

8. The radio frequency module according to claim 7, wherein
the first amplification device and the second amplification device are disposed on the first main surface.

9. The radio frequency module according to claim 1, wherein
the capacitor is a surface mount device.

10. The radio frequency module according to claim 1, wherein
the capacitor is a semiconductor component.

11. The radio frequency module according to claim 1, wherein
the power amplifier is a differential amplification type amplifier.

12. The radio frequency module according to claim 1, wherein
the first amplification device is a carrier amplifier or a peak amplifier,
the second amplification device is a carrier amplifier or a peak amplifier, and
the power amplifier is a Doherty amplifier.

13. The radio frequency module according to claim 1, wherein
the module substrate includes a ground electrode layer formed along a direction parallel to the first main surface or the second main surface, wherein
in a case where the module substrate is viewed in a plan view, the ground electrode layer is not formed in a region that overlaps the output transformer.

14. The radio frequency module according to claim 1, wherein the module substrate includes a low temperature co-fired ceramic (LTCC) substrate.

15. The radio frequency module according to claim 1, wherein the module substrate includes a High temperature co-fired ceramic (HTCC) substrate.

16. The radio frequency module according to claim 1, wherein the module substrate includes a substrate having a redistribution layer (RDL).

17. The radio frequency module according to claim 1, wherein the module substrate includes a printed circuit board.

18. A communication device comprising:
a signal processing circuit that processes a radio frequency signal; and
the radio frequency module according to claim 1 that transmits the radio frequency signal between the signal processing circuit and an antenna.

19. The communication device according to claim 18, wherein the signal processing circuit includes a radio frequency signal processing circuit (RFIC).

20. The communication device according to claim 18, wherein the signal processing circuit includes a base band signal processing circuit (BBIC).
